(19) United States
(12) Patent Application Publication
(10) Pub. No.: US 2014/0268538 A1
(43) Pub. Date: Sep. 18, 2014

(54) JBOD CABLE

(71) Applicant: Silicon Graphics International Corp., Fremont, CA (US)

(72) Inventors: Edmund G. Newbert, Longmont, CO (US); Michael J. Vega, Longmont, CO (US)

(21) Appl. No.: 13/931,796

(22) Filed: Jun. 28, 2013

Related U.S. Application Data
(60) Provisional application No. 61/780,880, filed on Mar. 13, 2013.

(51) Int. Cl. H05K 7/14

(52) U.S. Cl. CPC H05K 7/1498
USPC 361/679.33; 439/502; 439/77; 174/535

(57) ABSTRACT

Embodiments of the invention include a plurality of flexible electrical conductors configured as a cable wherein a plurality of signal pairs connect printed circuit boards in an array of data storage devices or just a bunch of disks (JBOD) enclosure. By controlling various specific dimensions relating to each signal pair of electrical conductors in a flexible cable, the performance of a JBOD box or a data storage server can be maximized. Furthermore, flexible cable designs can themselves replace bulkier circuit boards enabling greater air flow through the JBOD box or data storage server.

### CROSS REFERENCE TO RELATED APPLICATIONS

The present application claims the priority benefit of U.S. provisional application No. 61/780,880 filed Mar. 13, 2013 entitled “JBOD Cable,” the disclosure of which is incorporated herein by reference.

### BACKGROUND OF THE INVENTION

1. Field of the Invention

The present invention generally relates data cable. In particular, the present invention relates to cabling system engineered to maximize the packaging density of data storage devices in a storage enclosure.

2. Description of the Related Art

The modern data center contains a plurality of heterogeneous types of data storage equipment. Frequently, an array of data storage devices configured along with various printed circuit boards are packaged within an enclosure. The enclosure is a data storage array such as a box commonly referred to as Just a Bunch of Disks (JBOD) or a data storage server. Frequently JBOD boxes or data storage servers contain printed circuit boards configured as port expanders and a plurality of data storage devices. Port expanders are switches configured to switch several sets communication signals from one data storage device to another. Data storage servers typically include one or more compute engines performing server functionality where JBOD enclosures typically communicate with a server that is external to the JBOD enclosure. Thus both data storage servers and JBOD enclosures each typically use a plurality of cables connecting data storage devices or data storage subassemblies to other printed circuit boards contained within an enclosure.

The most common data storage device communication signals used in the data center today are low voltage differential signals configured in a plurality of pairs. Standard data storage device communication interfaces include serial attached SCSI (SAS) and serial attached ATA (SATA).

Both SAS and SATA communication interfaces contain two pairs of electrical conductors. One pair of these conductors is configured to transmit commands and data to a data storage device and the second pair of conductors are configured to receive data or other information from that same data storage device. Each set of two pairs of electrical conductors is commonly referred to as a data communication lane. The electrical conductors for each lane are commonly referred to as transmit X (TrX), transmit Y (TrY), read X (RdX), and read Y (RdY).

Frequently, data storage arrays have several circuit boards and a plurality of cables interconnecting those circuit boards. Typically, there are circuit boards that connect to devices external to the data storage array, there are circuit boards containing port expander circuits, and there are circuit boards configured to fan out (spread out) data storage device communication interconnections to a plurality of individual data storage devices.

Thus, data storage arrays contain many circuit boards with a plurality of cables connecting the different circuit boards electrically to each other and to a plurality of data storage devices. This means that the typical data storage array contains many connectors to which the cables connect. Each time a low voltage differential signal pair goes through a connector, the quality of that signal reduces. Signal quality is also reduced when transmitting signals over long distance. This causes designers of data storage arrays to incorporate repeater electronics into their designs, which in turn increases cost and adds another potential failure point in the design.

Each circuit board in a data storage array obstructs airflow through the box. Insufficient airflow in a data storage array increases the failure rate of data storage devices contained within the data storage array.

Factors that affect signal quality include conductor (trace) impedance, signal frequency, conductor (trace) length, conductor cross sectional area, the distance from a conductor to ground, and the number of connectors that a signal goes through. Typically, as signal frequency increases, signal quality reduces for a give conductor length. Thus, as signal frequency increases the maximum effective conductor length reduces.

As low voltage differential signal frequencies increase above 6 Giga bits per second, conventional data storage array designs will fail to maintain adequate signal quality. This will force designers of such enclosures to increase the number of signal repeaters significantly.

What is needed are improved electrical interconnections that minimize the number of connectors, repeaters, and circuit boards used in a data storage array enclosure.

### SUMMARY OF THE INVENTION

An embodiment of the invention includes a plurality of flexible electrical conductors configured as a cable wherein a plurality of signal pairs connect printed circuit boards in a data storage array such as a JBOD box or a data storage server. By controlling various specific dimensions relating to each signal pair of electrical conductors in a flexible cable, the performance of a data storage array can be maximized. Furthermore, flexible cable designs can themselves replace bulkier circuit boards enabling greater air flow through the data storage array.

The invention also relates to maximizing packaging density of the data storage array. Flexible cables consistent with the invention enable more data storage devices to be built into a data storage array enclosure of a particular size while allowing sufficient air flow to cool those data storage devices.

Flexible cables consistent with the invention may connect two or more printed circuit boards while minimizing the length of electrical conductors. Each cable may be configured to connect a plurality of signal pairs in a minimal volumetric space. Furthermore, circuit boards conventionally used in data storage array enclosures to fan out data communication lanes may be eliminated by the cable design.

The invention thus improves the electrical interconnections in a data storage array enclosure, minimizes the number of connectors by reducing the number of printed circuit boards, and eliminates the need to add signal repeaters to maintain signal quality.

### BRIEF DESCRIPTION OF THE DRAWINGS

FIG. 1 illustrates a top, side and bottom view of a flexible cable consistent with the invention.

FIG. 2 illustrates several three dimensional views of a flexible cable consistent with the invention.

FIG. 3 illustrates a top, and cross sectional side view of a flexible cable containing several signal pairs and a ground plane.

FIG. 4 illustrates a top, and cross sectional side view of another flexible cable containing several signal pairs and a ground plane.

FIG. 5 illustrates a conventional data storage array in a JBOD configuration.

FIG. 6 illustrates a data storage array in a JBOD configuration using flexible cables to connect signals to data storage subassemblies.

### DETAILED DESCRIPTION

An embodiment of the invention includes a plurality of flexible electrical conductors configured as a cable wherein a plurality of signal pairs connect printed circuit boards in a data storage array such as a JBOD box or a data storage server. By controlling various specific dimensions relating to each signal pair of electrical conductors in a flexible cable, the performance of a data storage array can be maximized. Furthermore, flexible cable designs can themselves replace bulkier circuit boards enabling greater air flow through the data storage array.

The JBOD cable is a flexible passive design configured to electrically communicate one or more lanes of low voltage data communication signals from a first connector to a plurality of data storage devices. In some embodiments two boards, top and bottom, (slightly different mechanically but identical electrically) are electrically connected to each other by flexible cables in the system. Their primary function is to route SAS requests and responses from boards or connectors to hot pluggable Expander system boards located within the enclosure. In some embodiments the Expander system boards are located on a mid-plane PCB, and in other embodiments Expander system boards are located in a data storage device subassembly containing a plurality of data storage devices within the enclosure.

Dimensions controlled by invention include:

the distance between each electrical conductor for a given signal pair;

the cross sectional area of each electrical conductor;

the conductor length for a given signal pair;

minimizing the number of connectors required that a particular signal pair is passed through in the data storage array;

the distance from the electrical conductors to ground; and

minimizing the length of signal pairs to or below an maximum length.

The invention also relates to maximizing packaging density of the data storage array enclosure. Flexible cables consistent with the invention enable more data storage devices to be built into a data storage array enclosure of a particular size while allowing sufficient air flow to cool those data storage devices.

Some embodiments of the invention use a plurality of vented frames designed to receive a plurality of data storage devices in a data storage device subassembly. For example a data storage device subassembly could contain 9 disk drives or solid state drives and a printed circuit board configured to electrically connect to the drives.

In these embodiments the data storage array could be configured to contain a plurality of data storage device subassemblies within an enclosure. Data communication signals from other printed circuit boards within the enclosure or from computing devices external to the data storage array may be distributed to data storage subassemblies within the enclosure through flexible cables consistent with the invention.

Data storage device subassemblies may contain an Expander configured to electrically communicate one or more lanes of low voltage data communication signals to individual data storage devices contained within a data storage device subassembly.

In certain other embodiments of the invention each data storage device subassembly is configured to be removed from the data storage array when the data storage array is shipped. Such a modular design allows each delicate data storage device subassembly to be shipped separately, within its own box.

Vented frames in certain embodiments of the invention allow air to flow through a data storage device subassembly and act to form a modular structure that facilitates ease of manufacturing and shipping. Typically vented frames are made of formed sheet metal configured to receive a plurality of disk drives and at least one printed circuit board.

In an exemplary embodiment of the invention an enclosure is configured:

to contain a data storage device subassembly in an enclosure; and

to electrically communicate at least one lane of low voltage data communication signals from a first connector to at least one data storage device subassembly through a flexible cable consistent with the invention to a first data storage device subassembly;

The invention may also contain a second data storage device subassembly configured to electrically communicate at least one lane of low voltage data communication signals from a first connector to at least a second data storage device subassembly.

The invention is extensible, it may contain a plurality of data storage device subassemblies, one or more of flexible cables, and one or more connectors configured to electrically communicate low voltage differential signals from one or more connectors to a plurality of data storage device subassemblies through one or more flexible cables.

FIG. 1 illustrates a top, side, and bottom view of a flexible cable consistent with the invention. The top side of the flexible 101a cable of FIG. 1 depicts a cable before any connectors have been installed. The side view 101b, and bottom view 101c depict stiffeners attached to the flexible cable of FIG. 1. Certain embodiments of stiffeners include, but are not limited to, conventional printed circuit board materials such as FR4—a composite material composed of woven fiberglass cloth with an epoxy resin binder that is flame resistant. Certain embodiments of the invention will use such stiffeners to support connectors that will typically be mounted to the top side of the flexible cable.

FIG. 2 illustrates several three dimensional views of a flexible cable consistent with the invention. A first three dimensional view in FIG. 2 shows the flexible cable 201a containing connectors 210, 220, and 230. Folds or exceptionally flexible points in the flexible cable are depicted as dashed lines F. A second three dimensional view shown in FIG. 2 depicts a top view 201b; also depicted are connectors 210, 220, and 230. Connector 220 in this view is standing perpendicular to the flexible cable 201b. The third three dimensional view in FIG. 2 depicts a side view of the flexible cable 201c. Here again connectors 210, 220, and 230 are depicted. The flexible cable 201c has been folded such that connector 230 is standing perpendicular to the surface of the figure, and connector 220 is facing upward.

FIG. 3 illustrates a top and cross sectional side view of a flexible cable containing several signal pairs and a ground plane. The top view of the flexible cable in FIG. 3 shows the flexible cable 301a containing a plurality of electrical conductors in signal pairs 302a. The cross sectional side view in the figure shows the flexible circuit 301b including a trace layer 302b and ground plane 303.

FIG. 4 illustrates a top, and cross sectional side view of another flexible cable containing several signal pairs and a ground plane. The top view of the flexible cable in FIG. 4 shows the flexible cable 401a containing a plurality of electrical conductors in signal pairs 402 originating from a first end E1 of flexible cable 401a. Half of the electrical conductor signal pairs 402a route to a second end E2 of flexible cable 401a, and the other half of the electrical conductor signal pairs 402b route to a third end E3 of flexible cable 401a. FIG. 4 also shows a cross sectional side view of the flexible cable 401b that includes a ground plane 403 and a trace layer 402.

FIG. 5 illustrates a conventional data storage array in a JBOD configuration. FIG. 5 shows a Semi-Cross Sectional Side View and a Semi-Cross Sectional Top View of the data storage array DSA. The data storage array DSA contains a plurality of fans F, two JBOD interface connectors JBOD I/O Conn mounted on a JBOD interface printed circuit board JBOD I/O PCB, a mid-plane printed circuit board M, a plurality of cables C, and a plurality of data storage subassemblies (DSS0, DSS1, DSS2, and DSS3).

The Semi-Cross Sectional Top View shows of FIG. 5 the JBOD interface printed circuit board JBOD I/O PCB electrically connected to the mid-plane circuit board M with 4 cables C, and shows the mid-plane circuit boards connecting to 4 data storage subassemblies (DSS0, DSS1, DSS2, and DSS3) using another set of 4 cables C. The JBOD interface connectors JBOD I/O Conn are where cables connecting the data storage array DSA to computers that are external to the data storage array DSA.

FIG. 6 illustrates a data storage array in a JBOD configuration using flexible cables to connect signals to data storage subassemblies. FIG. 6 shows a Semi-Cross Sectional Side View and a Semi-Cross Sectional Top View of the data storage array DSA. The data storage array DSA contains a plurality of fans F, two JBOD interface connectors JBOD I/O Conn mounted on a JBOD interface printed circuit board JBOD I/O PCB, and two flexible cables FC connecting a plurality of data storage subassemblies (DSS0, DSS1, DSS2, and DSS3) to the JBOD interface printed circuit board JBOD I/O PCB.

FIG. 6 shows flexible cables FC directly connecting the JBOD interface printed circuit board to the data storage subassemblies (DSS0, DSS1, DSS2, and DSS3) using connectors FConn on the the flexible cable FC. Flexible cables FC are also located under and attached to the data storage sub assemblies (DSS0, DSS1, DSS2, and DSS3).

The Semi-Cross Sectional Top View of FIG. 6 shows portions of flexible cables FC located under the data storage subassemblies (DSS0, DSS1, DSS2, and DSS3) with dashed lines. Portions of the cables not located under the data storage subassemblies (DSS0, DSS1, DSS2, and DSS3) are depicted with solid lines.

The flexible cables FC in FIG. 6 reduces the total number of connectors and cables used in the data storage array DSA. The low voltage differential signals of FIG. 6 only go through three connectors the JBOD interface connector JBOD I/O Conn, a connector FConn connecting the JBOD interface printed circuit board JBOD I/O PCB flexible cable FC, and a connector FConn connecting to one of the data storage subassemblies (DSS0, DSS1, DSS2, and DSS3). In contrast the data storage array of requires 5 connectors to connect low voltage differential signals to a data storage sub assembly (DSS0, DSS1, DSS2, and DSS3).

The additional connectors required to build the data storage array DSA of FIG. 5 degrade signal quality of the low voltage differential signals causing designers to use signal repeaters as the frequency of the low voltage differential signals are increased above 6 Giga bits per second. Thus designs that would function at frequencies of 6 Giga bits per second and below will not function as signal frequencies are increased.

The flexible cables also allows designers to reduce the number of printed circuit boards in the data storage array, increasing the air flow through the data storage array. The flexible cables also allow the low voltage differential signals to be routed under and around obstacles and subassemblies. The flexible cables also have smaller bend radiuses than conventional high speed cables used to transfer low voltage differential signals. In some embodiments the flexible cables can be folded at extreme angles. For example in some embodiments they can be folded in half.

Flexible cables consistent with the invention may connect two or more printed circuit boards while minimizing the length of electrical conductors. Each cable may be configured to connect a plurality of signal pairs in a minimal volumetric space. Furthermore, circuit boards conventionally used in JBOD enclosures or data storage servers to fan out data communication lanes may be eliminated by the cable design. Flexible cables may be flex circuits with square or rectangular electrical conductors (in cross section) or they may be wires built into a cable. Flexible cables consistent with the invention typically contain insulation between trace layers and layers that contain signal grounds. The invention may have a plurality of layers wherein some layers are predominantly insulating and other layers contain traces and/or signal grounds. A first layer that is predominantly insulating is herein considered a substrate upon which traces or signal grounds may be fabricated.

The invention thus improves the electrical interconnections in a JBOD enclosure, by minimizing the number of connectors by reducing the number of printed circuit boards, and eliminating the need to add signal repeaters to maintain signal quality. The invention also increases the cooling efficiency of the enclosure by increasing air flow through the enclosure.

What is claimed is:

1. A flexible cable, comprising:
a plurality of flexible electrical conductors configured as a plurality of pairs of flexible electrical conductors wherein each of a first flexible electrical conductor in each particular pairs of flexible electrical conductors is located at a controlled distance from a corresponding second electrical conductor in each of the particular pairs of flexible electrical conductors, and wherein each of the first flexible electrical conductors and each of the corresponding second electrical conductors have a controlled cross sectional area and a controlled length; and
at least two electrical connectors wherein at least one electrical connector is connected to a first end of the flexible cable, and at least one other electrical connector is connected to a second end of the flexible cable.

2. The flexible cable of claim 1 further comprising:
the a plurality of flexible electrical conductors each configured a controlled distance from a signal ground; and
wherein the controlled cross sectional area and the controlled length of each of the first flexible electrical conductors and each of the corresponding second electrical conductors, the at least two electrical connectors, and the controlled distance from a signal ground to the plurality of flexible electrical connectors is optimized to transfer low voltage differential signals with speeds of 10 giga bits per second or greater.

3. The flexible cable of claim 2, further comprising a printed circuit board to which the plurality of flexible electrical conductors and the signal ground are physically attached.

4. The flexible cable of claim 2, wherein the plurality of pairs of flexible electrical conductors are wires.

5. The flexible cable of claim 3, further comprising a first printed circuit board material connected to a portion of a flexible substrate, the flexible substrate configured to support at least one of the at least two electrical connectors, and wherein a second printer circuit board material connected to another portion of the flexible substrate configured to support at least one other of the at least two electrical connectors.

6. The flexible cable of claim 2 further comprising:
a plurality of data storage devices;
an enclosure containing the plurality of data storage devices and the flexible cable; and
a first connector configured to electrically communicate at least one lane of low voltage data communication signals from the connector to at least one particular data storage device through the flexible cable.

7. The flexible cable of claim 5 further comprising:
a first vented frame configured to receive a first plurality of data storage devices forming a first data storage device subassembly;
a second vented frame configured to receive a second plurality of data storage devices forming a second data storage subassembly; and
wherein the flexible cable electrically connects a first set of the plurality of low voltage differential signals from the first connector to the first data storage device subassembly and wherein the flexible cable electrically connects a second set of the plurality of low voltage differential signals from the first connector to the second data storage device subassemblies.

8. The flexible cable of claim 6 further comprising:
a port expander contained within each of the data storage device subassemblies.

9. The flexible cable of claim 6 further comprising:
a plurality of flexible cables each connecting low voltage differential data communication signals to one or more data storage device subassemblies.

10. The flexible cable of claim 8 further comprising:
a plurality of connectors configured to electrically communicate at least one lane of low voltage data communication signals from each of said plurality of connectors to at least one of the one or more data storage device subassemblies through at least one of the one or more plurality of flexible cables.

11. The flexible cable of claim 9 wherein each of the one or more data storage device subassembly is configured to be removed from the data storage array for shipping.
